(19) United States
(12) Patent Application Publication
(10) Pub. No.: US 2026/0235966 A1
(43) Pub. Date: Aug. 13, 2026

(54) Out-Coupling Techniques for Accelerator-based Light Sources in Semiconductor Metrology and Inspection Applications

(71) Applicant: yTools, Inc., Capitola, CA (US)

(72) Inventor: William A Schumaker, Capitola, CA (US)

(73) Assignee: yTools, Inc., Capitola, CA (US)

(21) Appl. No.: 19/264,804

(22) Filed: Jul. 9, 2025

Related U.S. Application Data
(60) Provisional application No. 63/755,351, filed on Feb. 7, 2025.

(51) Int. Cl. G03F 7/00

(52) U.S. Cl. CPC G03F 7/706847; G03F 7/70316

(57) ABSTRACT

Out-coupling techniques for an accelerator-based EUV/SXR light source. One or more optics are designed to “pick off” and redirect one or more portions of the source light beam, namely, specified harmonics, for use in semiconductor metrology and inspection applications.

### TECHNICAL FIELD

This disclosure relates generally to semiconductor metrology and inspection, and more particularly to techniques for coupling the output of an accelerator-based light source, namely, a light beam having wavelengths in the EUV/SXR range, for use in semiconductor metrology and inspection applications.

### BACKGROUND

Semiconductor metrology systems and inspection systems are used for a variety of process and quality control applications in the manufacture of semiconductor devices. Further, the use of narrow and broadband accelerator-based light sources is known for characterizing nanoscale features of semiconductor devices. Extreme ultraviolet (“EUV”) light ranges from approximately 10-120 nm and has been used for lithography, and yet smaller wavelengths in the 0.1-10 nm range are considered “soft” X-rays (“SXR”). For example, X-ray scatterometry, such as critical dimension small angle X-ray scattering (CD-SAXS), is a technique for measuring and characterizing nanoscale features in a semiconductor target sample that utilizes a light source to generate a light beam in the EUV/SXR range for the metrology tool. (See, e.g., https://www.nist.gov/programs-projects/critical-dimension-small-angle-x-ray-scattering-cdsaxs-next-generation-line).

It would be desirable, however, to extend the capabilities of metrology and inspection tools by offering a significant improvement in the overall throughput and performance of such systems via compatibility with more powerful accelerator-based light sources and improved optical control.

### BRIEF SUMMARY

Out-coupling techniques are described for use with an accelerator-based EUV/SXR light source. A mirror (or a series of mirrors) is configured as an optical aperture, either on-axis or near-axis (an inner aperture) or off-axis (an outer aperture). As an inner aperture, the mirror reflects and redirects the desired harmonic(s) in one direction while minimally interfering or interacting with the fundamental harmonic, which passes in the original direction. As an outer aperture, the mirror reflects and redirects the fundamental harmonic while passing other odd harmonic(s) through a relatively narrow opening in the aperture. Alternatively, an outer aperture mirror can reflect and redirect the desired harmonic(s) while passing the fundamental harmonic through a relatively larger opening in the aperture.

### BRIEF DESCRIPTION OF THE DRAWINGS

The various Drawings and Detailed Descriptions thereof are intended to be illustrative examples, not limiting, and not are necessarily accurate from a dimensional or angular perspective; for example, all mirror and reflection angles are exaggerated for clarity.

FIG. 1 is a perspective view illustrating the spatial distribution of odd harmonics in a light beam emitted from an accelerator-based light source.

FIG. 2 is a perspective view illustrating the spatial distribution of the second harmonic in the emitted light beam of FIG. 1.

FIG. 3 is a simplified block diagram illustrating one embodiment of an optical system for out-coupling an accelerator-based light source into various applications by redirecting the higher-order harmonics including some of the fundamental harmonic.

FIG. 4 is a simplified block diagram illustrating another embodiment of an optical system for out-coupling an accelerator-based light source into various applications by redirecting the fundamental harmonic.

FIG. 5 is a simplified block diagram illustrating the addition of a harmonic separation optic to an out-coupling optic.

FIG. 6 is a simplified block diagram illustrating an accelerator-based light source.

FIG. 7 is a perspective view of a thin wedge-shaped mirror positioned to pick-off and reflect odd harmonics on the central axis of the light beam.

FIG. 8 is a perspective view of a mirror suspended in position to pick-off and reflect odd harmonics on the central axis of the light beam.

FIG. 9 is a perspective view of a mirror having a central opening sized for passing through the higher order odd harmonics on the central axis of the light beam, and reflecting the fundamental harmonic.

FIG. 10 is a perspective view of a mirror having a central opening sized for passing the fundamental harmonic, and reflecting the even harmonics.

FIG. 11 is a perspective view illustrating one example of multiple out-coupling stages cascaded together.

FIG. 12 is a perspective view illustrating another example of multiple out-coupling stages cascaded together.

FIG. 13 is a side view of an optical grating in the path of the source light beam to reflect and redirect desired harmonics of the beam.

FIG. 14 is a side view of the optical grating of FIG. 13 redirecting each of the separated harmonics to a corresponding mirror for routing to different metrology and/or inspection tools.

### DETAILED DESCRIPTION

In the following examples, optical techniques are described for coupling the light beam output from an accelerator-based EUV/SXR light source in order to “pick off” desired odd and/or even harmonics of the light beam for use in semiconductor metrology and inspection applications, separate and apart from a primary use of the first or fundamental harmonic in lithography tools. For simplicity, as used in this Detailed Description to describe the light source and/or light beam, the term “EUV” should be considered interchangeable with and/or encompassing the term “SXR.” Since each harmonic of an EUV light beam has a known emission pattern from the light source, optics can be designed to select a portion of the light beam to “pick off” the different harmonics for different and/or parallel uses in metrology and inspection tools. Of course, a key concern is ensuring that out-coupling the desired light from a portion of the source beam results in minimal impact to other applications, such as the primary application for the light beam in lithography.

Accelerator-based light sources produce synchrotron radiation, which results from charged particles traveling in curved paths created by magnetic fields. The angular distribution of a light beam emitted from an accelerator-based light source (i.e., the light beam consists of a fundamental harmonic and higher order odd and even harmonics) is complex, but can be determined from the Schwinger Equation for synchrotron radiation. (See, e.g., https://www.nist.gov/pml/sensor-science/what-synchrotron-radiation#:~:text-Synchrotron%20radiation%20is%20the%20electromagnetic,is%20also%20called%20Magneto%2DBremsstrahlung.)

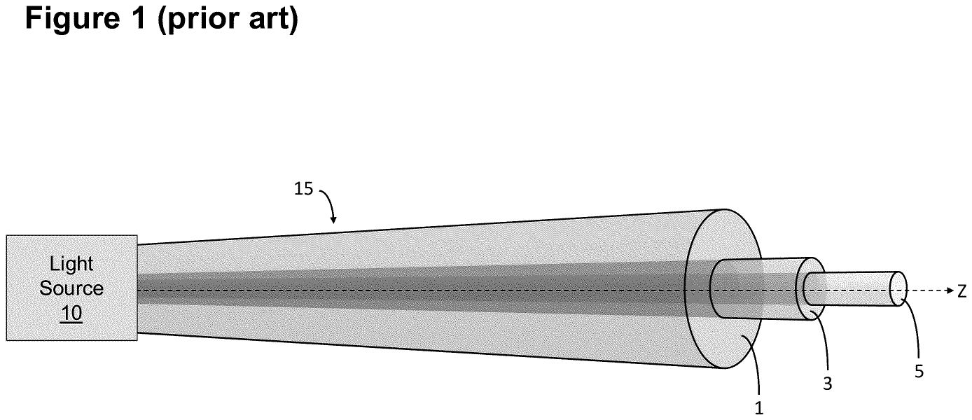

In general, odd harmonics from accelerator-based light sources are emitted on-axis to the beamline of the light beam. As shown in FIG. 1, a light beam 15 generated by an accelerator-based light source 10 expands in a cone shape around the beamline axis Z as it is emitted from the light source and includes the first or fundamental harmonic 1, the third harmonic 3, the fifth harmonic 5, and other harmonics not shown. For example, for an EUV light source 10 generating a light beam 15 having a fundamental harmonic of 13.5 nm, the light beam has an emission pattern that appears as a relatively large cone angle expanding on-axis with the beamline axis Z, as determined by the undulator and electron beam parameters of the accelerator-based source. Thus, the fundamental or first harmonic 1 is emitted with the largest cone angle while the higher order odd harmonics typically have an on-axis cone angle that is the harmonic number fraction of the first order cone angle in both dimensions. Therefore, in this example, the cone angle of the third harmonic 3 (e.g., 4.5 nm) is one-third the size of the first harmonic cone angle; and the cone angle of the fifth harmonic 5 (e.g. 2.7 nm) is one-fifth the size of the first harmonic cone angle, and so forth.

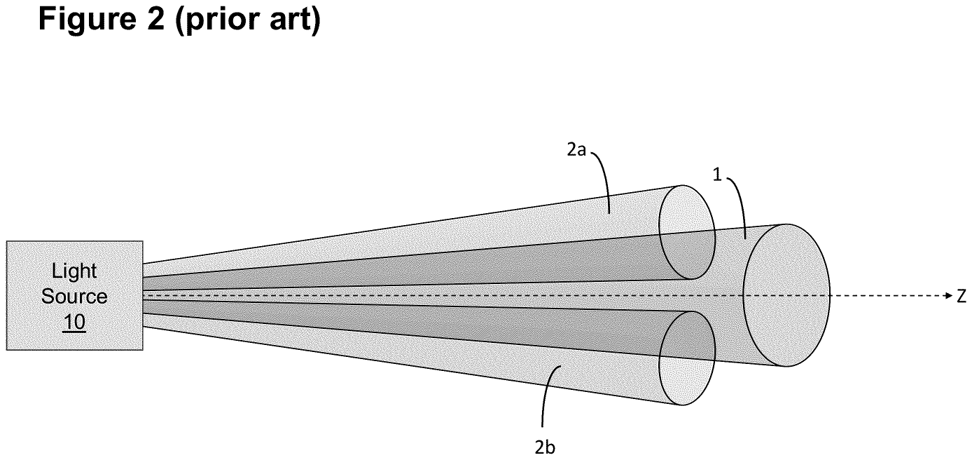

The even harmonics are more complex. Rather than being centered around the beamline axis, the even harmonics are emitted slightly off-axis and may fall outside the emission cone of the fundamental harmonic. As shown in FIG. 2, for example, the second harmonic 2 appears as two different portions 2a and 2b that, when emitted from the source 10, are centered around the edges of the fundamental harmonic 1. The even harmonic portions 2a and 2b are more lobe-shaped as a result of a complex function of the electron beam and undulator parameters as well as the amplified gain profile over subsequent undulators. (See, e.g., D. Atwood, “Beam Parameters, Spectral Brightness, Harmonics and Wiggler Radiation,” UC Berkeley EE290F. 20 Feb. 2007; https://people.eecs.berkeley.edu/~attwood/srms/2007/Lec11.pdf). Other higher order even harmonics also have complex emission patterns that are off-axis of the beamline.

With knowledge of these emission characteristics, optical structures can be built to “pick off” the desired harmonics separate and apart from the fundamental (although some portion of the fundamental may also be picked off by the optics). Of course, high levels of precision and quality are required to construct suitable optical structures since the power levels of the accelerator-based source beams are high (up to 10 kW or more), and optical structures and their coatings are highly sensitive to damage, especially with high power gradients in the small powerful beams emitted from accelerator-based light sources.

Thus, an out-coupling optic placed proximate to an EUV light source will be a mirror configured as an optical aperture either on-axis or near-axis (an inner aperture) or off-axis (an outer aperture). In one embodiment, the mirror is designed as an inner aperture to reflect and redirect the desired odd harmonic(s) of the light beam in one direction while minimally interfering or interacting with the fundamental harmonic, which simply passes on to its primary application, e.g., a lithography tool, without much loss of power. Another embodiment configures the out-coupling mirror as an outer aperture to reflect and redirect the fundamental harmonic while passing the odd harmonic(s). Further, since the even harmonics from accelerator-based light sources are emitted off-axis, another embodiment again configures the out-coupling optic mirror as an outer aperture, but in this example, designed to reflect and redirect the off-axis even harmonic(s) while passing the fundamental harmonic into a lithography tool.

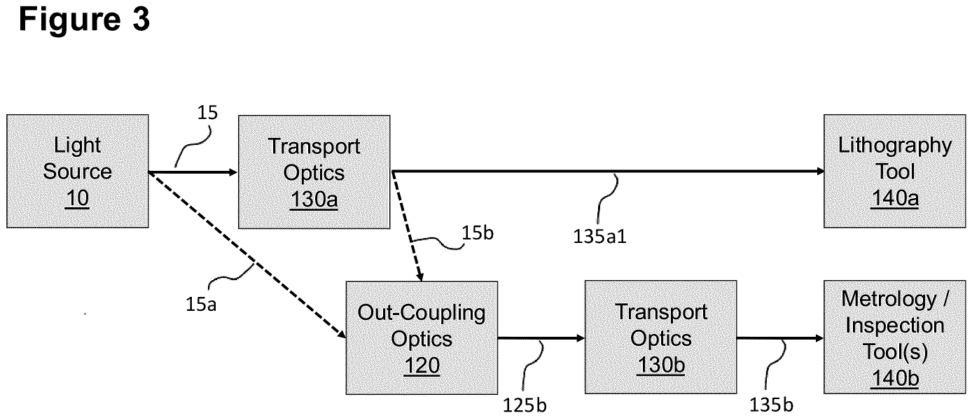

FIGS. 3-5 are schematic block diagrams illustrating several different examples of how to use out-coupling optical systems with an accelerator-based light source for semiconductor metrology and/or inspection. In these examples, light source 10 generates a broadband light beam 15 having a fundamental wavelength in the EUV/SXR range, e.g., approximately 3-20 nm.

FIG. 3 illustrates the simple “pick-off” concept. Along the primary path, the source 10 outputs light beam 15, typically via transport optics (not shown). The light beam is provided as target beam 135a1 directly to the primary application, namely, lithography tool 140a, typically via transport optics 130a, with minimal interaction with the out-coupling optical elements 120.

The out-coupling optical elements 120 are designed to isolate desired harmonic wavelength(s) to provide as an input beam for an additional specified semiconductor task, such as inspection and/or metrology. In this example, the out-coupling optical elements 120 are configured to pick off a portion 15a of the source beam 15 having the desired or specified harmonics for another application and redirect the picked-off harmonics along a secondary path to that application. Portion 15a may be captured directly from the source 10 prior to transport optics 130a, or alternatively, portion 15b may be captured after the transport optics 130a. The out-coupling optics 120 generate beam 125b, which is comprised of one or more harmonics as specified for a particular metrology or inspection application. The beam 125b is then directed into appropriate transport optics 130b for use as target beam 135b in one or more metrology and/or inspection tool(s) 140b.

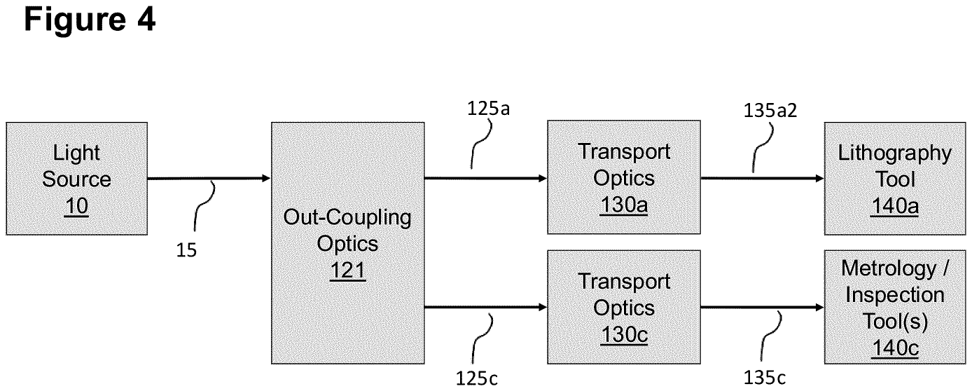

In FIG. 4, the source 10 outputs light beam 15, which is again typically coupled via transport optics (not shown) with one or more optical elements 121. In this example, the out-coupling optical elements 121 isolate a first beam 125a, namely the first or fundamental harmonic, which may then be directed via appropriate transport optics 130a as target beam 135a2 into a lithography tool 140a as usual, with only a modest reduction in the power of target beam 135a2. The out-coupling elements 121 can be configured to also isolate (or “pick off”) a second portion of the light beam 15 to generate beam 125c, consisting of a higher order harmonic and some fundamental, which is then directed through a different set of transport optics 130c to generate target beam 135c into one or more metrology and/or inspection tools 140b.

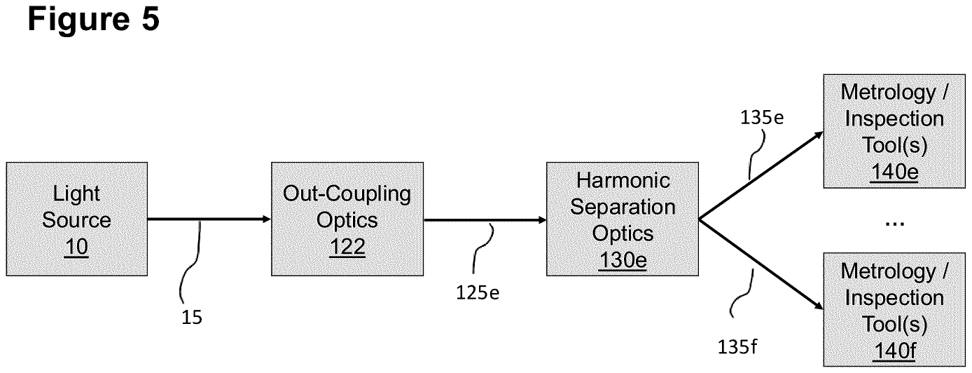

FIG. 5 extends the pick-off scenarios illustrated in FIGS. 3-4 by adding another set of optics 130e that are designed to separate the different harmonics. Thus, out-coupling optical elements 122 are used to pick off harmonics from the source beam 15, which are directed as beam 125e into optics 130e, where the different harmonics contained in beam 125e can be directed into different tools. For example, the harmonic separation optics can separate and reflect in different directions a first beam 135e having one of the harmonics (e.g., the third harmonic) for use in metrology or inspection tool(s) 140e, and into a second beam 135f having a different one of the harmonics (e.g., the fifth harmonic) for use in other metrology or inspection tool(s) 140f.

It should be obvious that many different combinations of optical elements can be configured and used to pick off harmonic content from the source beam for use in a particular semiconductor application or tool. Several detailed examples are discussed below. Further, although transport optics are discussed in the examples above and will typically be used both before and after the out-coupling optics, in some scenarios, transport optics may not be required, and the out-coupled light beam can be provided directly into the relevant tool.

### 1. The Light Source

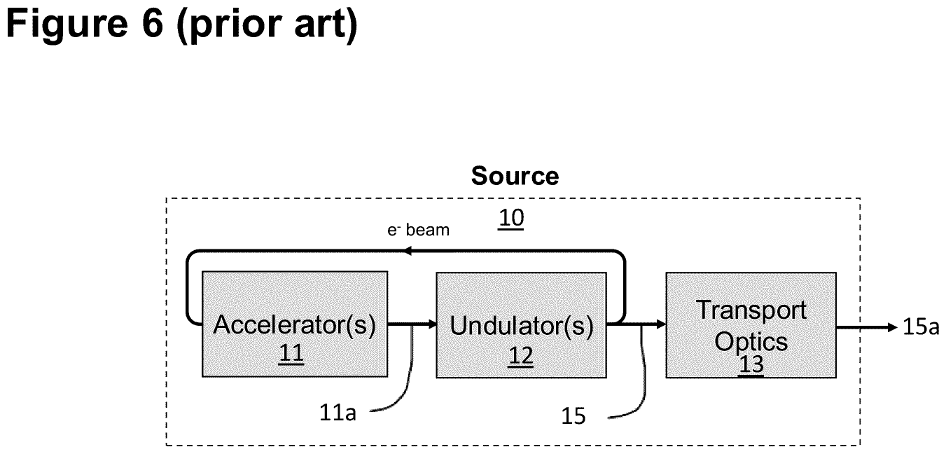

As shown in FIG. 6, a preferred light source 10 includes one or more particle accelerator modules 11 that function in a known manner to generate a low-emittance beam 11a of high-energy electrons. The electron beam 11a is passed through an undulator network 12 that uses periodic magnetic fields in a known manner to convert some of the electron beam energy into a narrow bandwidth light beam 15 of high-intensity synchrotron radiation. Typically, the electron beam is recirculated back to the accelerator module 11 after passing through the undulator network 12. Optionally, as noted above, the light source 10 may also include transport optics 13 to collect the light beam 15 from the undulator(s) 12 and transport it as source beam 15a through a beam tube (not shown) to the appropriate platform. For the purposes of this disclosure, references to the source beam 15 should be construed to include beam 15a delivered via transport optics 13 provided with the source 10.

Accelerator-based sources are becoming commercially available as FELs (free-electron lasers) that generate high-energy, narrowband light beams from EUV wavelengths down into the SXR range. For example, an FEL source for semiconductor applications can generate an output light beam having a fundamental wavelength (e.g., 13.5 nm); but other harmonic wavelengths of the light beam can be harvested for use in a metrology tool or other application, as described herein. For example, higher order harmonics of the FEL source output could be selected for use as wavelengths of interest in a metrology tool or an inspection tool, such as the third harmonic (e.g., 4.5 nm) or the fifth harmonic (e.g., 2.7 nm), and so on, even when the first or fundamental harmonic is used for other purposes.

### 2. Out-Coupling from the Light Source

Given the understanding of emission patterns for odd and even harmonics and the EUV range, two categories of optical methods are described: an inner optical aperture designed to reflect the on-axis or near-axis odd harmonics; and an outer optical aperture designed either to pass on-axis or near-axis odd harmonics and reflect the fundamental, or to reflect the off-axis even/odd harmonics. Examples are described below. It should be noted that the various pick-off optics could have curved surfaces, not just flat as depicted, which could magnify or de-magnify the picked-off beam.

### A. Method One: Inner Wedge Pick-Off

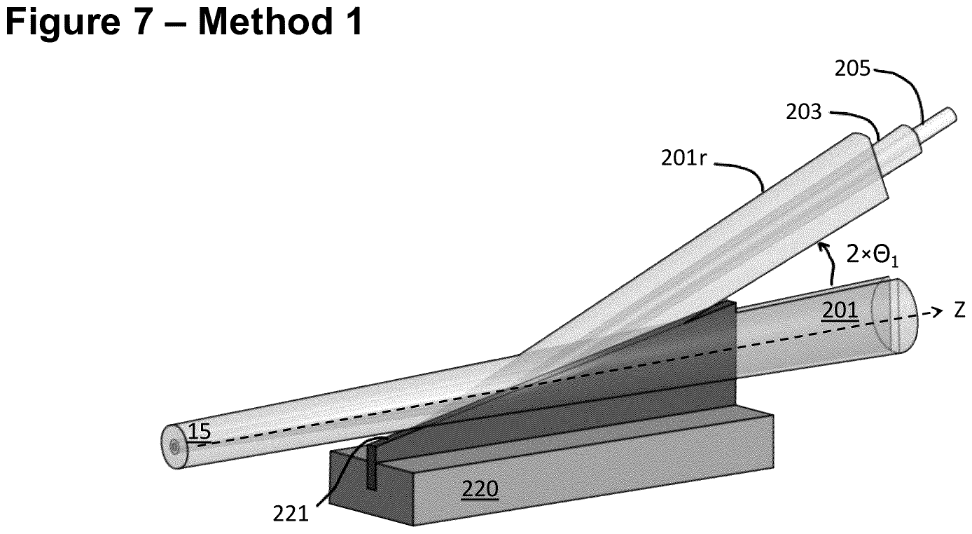

Referring to FIG. 7, a mirror 220 is fixed in a position that is proximate to an EUV source (not shown) and intersects with the source beam 15 such that the reflective surface 221 of the mirror is oriented at an appropriate angle Θ1 to the beamline axis Z such that the reflected beams 201r, 203, and 205 are reflected at an angle of two times Θ1 with respect to beam 201. In this example, the mirror 220 is relatively thin and wedge-shaped, thereby forming a small inner optical aperture designed to reflect the higher order odd harmonics of beam 15 that, as noted above, have a smaller cone angle as more tightly focused around the beamline axis Z than the fundamental harmonic when emitted from the source. Thus, most of the larger cone of the fundamental harmonic 201 simply passes by the thin mirror 220 without interacting with the mirror. The reflective surface 221 of the mirror 220 is configured with appropriate coatings to reflect the desired odd harmonics, for example, the third harmonic 203 and the fifth harmonic 205 of beam 15. The inner aperture design is therefore effective in capturing these odd harmonics and redirecting them in a different direction with only minor impact on the fundamental harmonic. Of course, some small residual portion 201r of the fundamental harmonic may also be reflected by the inner aperture along with the higher order harmonics. However, most of the fundamental harmonic is not reflected by placing a thin, wedge-shaped mirror across the axis of the beamline Z as shown, as only a small portion of the fundamental will be picked-off by the mirror as an inner aperture. Therefore, a significant amount of the energy in the fundamental harmonic 201 can and will still be passed to the primary application (e.g., lithography). The various implementations of mirror 220 to select and use wavelengths of interest require specifying the substrate (e.g., silicon or silicon carbide), its geometry and/or surface coatings as necessary.

### B. Method Two: Inner Suspended Pick-Off

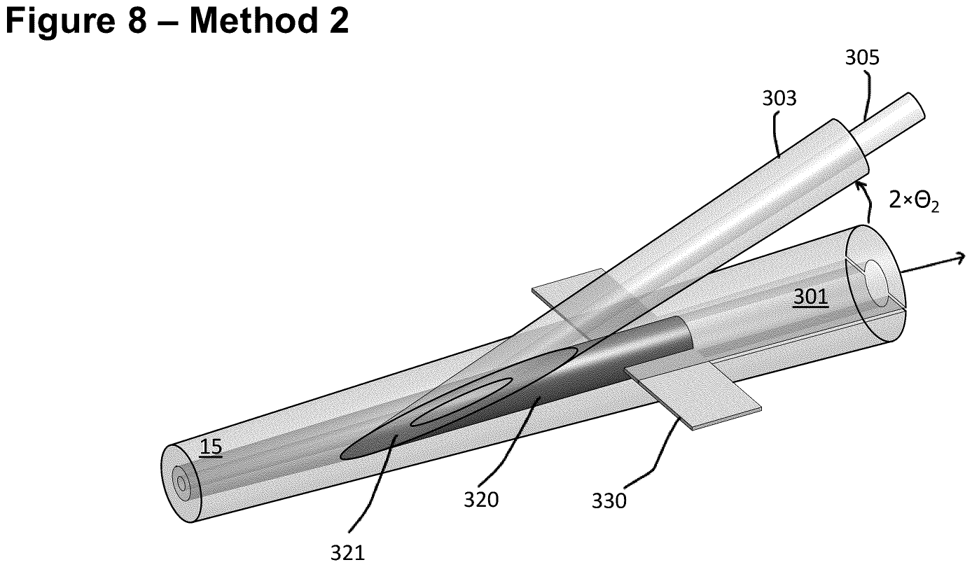

FIG. 8 illustrates another optical structure embodiment configured as an inner aperture for reflecting the odd harmonics. A mirror 320 is placed on-axis or nearly on-axis (i.e., “near-axis”) with beam 15 to form an inner aperture having a reflective surface 321 that is oriented at an appropriate angle Θ2 to the beamline axis such that beams 303 and 305 are reflected at an angle of two times Θ2 with respect to beam 301. In this example, the mirror 320 is suspended in position by a physical support structure 330. The mirror 320 could be made from silicon or silicon carbide or other suitable materials, whereas the support structure 330 must provide adequate mechanical and thermal stability for the mirror 320, for example, aluminum or silicon carbide struts, and not unduly impinge upon the source beam 15.

The inner aperture design of mirror 320 may be large enough to cover virtually the entire emitted cone(s) of the higher odd harmonics (e.g., the third harmonic 303 and the fifth harmonic 305), or the aperture could be made smaller for a select subset of the odd harmonics (and also some small residual portion of the fundamental 301). The inner aperture could be positioned either exactly on-axis or nearly on-axis, i.e., near-axis. The selected odd harmonics are redirected to, for example, a metrology tool while passing most of the fundamental harmonic to a lithography tool. Although the illustrated embodiment of structure 330 includes support legs arranged at various angles to each other around the cone of the source beam, other support configurations are of course possible. In this example, the inner optical aperture formed by the mirror 320 is configured to reflect the third harmonic 303 and the fifth harmonic 305 while the fundamental 301 passes with minimal interaction. Further, while the aperture in this example is fabricated and illustrated as circular, it is effectively elliptical in place as a result of being oriented at a grazing angle. There are no limitations on the shape and positioning of an aperture other than as dictated by the need of the application, including on-axis or near-axis positioning.

Once again, suitable mirror constructions require identifying the substrate (e.g., silicon or silicon carbide), the shape of the mirror and its supports, and its surface features and/or coatings as necessary.

### C. Method Three: Pass-Through Pick-Off

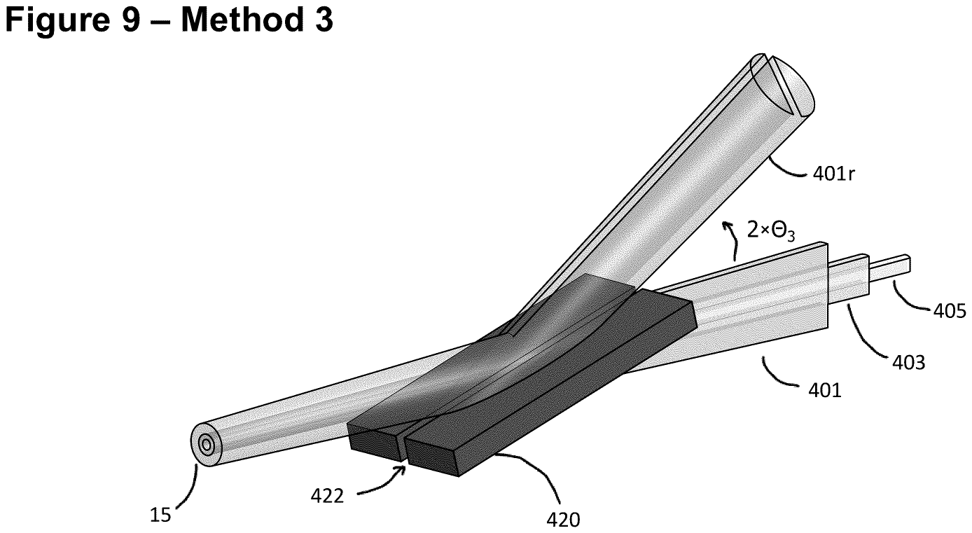

FIG. 9 illustrates an embodiment of an out-coupling structure for the source beam 15 that implements the converse relationship, namely, an outer aperture mirror design, wherein the higher order odd harmonics are passed through a small on-axis or near-axis opening in the out-coupling optic sized for those harmonics and the fundamental is reflected by the outer aperture created by the out-coupling optic. In this example, mirror 420 is positioned at an appropriate angle Θ3 relative to the axis of the source beam 15 and provided with a small gap 422 between, for example, two mirror portions. The small size of the gap 422 allows some of the fundamental harmonic 401, the third harmonic 403, and fifth harmonic 405 to pass through the gap, consistent with the on-axis emission patterns, while most of the fundamental harmonic 401r is reflected by the outer aperture design of the mirror 420 at an angle of two times Θ3 with respect to beams 401, 403, 405. Alternative designs that could provide the same result include a single mirror having a pin hole formed through the mirror or a central notch removed from the mirror allowing the higher order odd harmonics to pass through a central opening in the mirror rather than be reflected. These alternatives may be difficult in practice since the required length of a realistic grazing mirror would make it difficult to drill a high-precision hole or form a notch or similar “through-hole” feature.

These embodiments take advantage of the fact that spectral distribution from the light beam of an EUV source is spatially distinct in terms of its angular spread. By out-coupling the source beam 15 using an outer aperture mirror structure, only a small percentage of the fundamental harmonic energy is lost, but a significant portion of the desired higher order harmonic content can be obtained for metrology in those smaller slices of the light source output.

While the mirror portions shown in FIG. 9 are arranged in parallel with each other, that need not be the case. For example, if the mirror portions are not parallel but fixed at different angles or offsets, then the fundamental could be reflected and redirected in two different directions.

### D. Method Four: Outer Pick-Off

As noted above, the even harmonics have a slightly off-axis spatial distribution as emitted from an EUV source, compared to the on-axis odd harmonics. These complex emission patterns are due to the electron beam emitting at relativistic energies; however, once again, knowledge of the emission patterns means that a portion of the even harmonics can be collected on the periphery of the fundamental harmonic beam and provide a useful role in metrology or other applications. Whereas the fundamental harmonic beam is emitted in a cone angle approximately given by

$$\frac{1}{γ} ,$$

where γ is a relativistic factor of the electron beam in the undulator, the second harmonic is emitted in lobes approximately centered around the

$$\frac{1}{γ}$$

cone angle of the fundamental. Higher order even harmonics (4th, 6th, etc.) have different angular distributions as a function of the electron motion in the undulator and will have some emission outside of the fundamental cone which can also be collected.

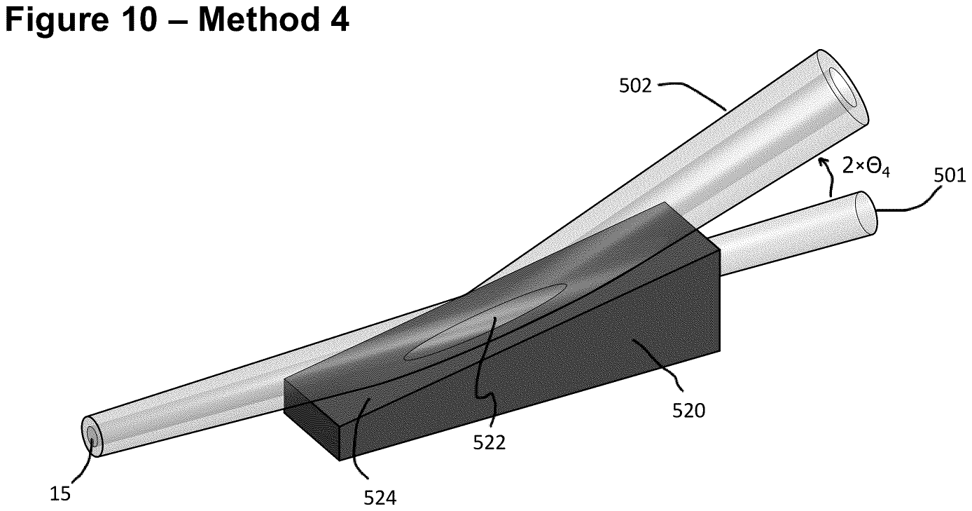

For example, referring to FIG. 10, mirror 520 is positioned at angle Θ4 to the beamline axis in appropriate proximity to the light source such that beam 502 is reflected at an angle of two times Θ4 with respect to beam 501. The mirror 520 has a large central opening 522 formed through the center of the mirror to pass the fundamental 501 and other on-axis odd harmonics and which serves to define the outer aperture reflective surface 524 with appropriate coatings. In this example, the opening 522 is circular thereby defining the reflective surface 524 as circular or ring-shaped in order to reflect the even harmonics 502 from an edge of the fundamental harmonic 501 and redirect the even harmonic in a different direction than the fundamental 501 to another appropriate metrology or inspection tool.

As in the Method Three example for the odd harmonics described above, instead of a ring-shaped mirror, two or more mirror portions could be positioned with a large gap between them, the gap sized to pass the fundamental harmonic. However, the principle remains the same—the outer apertures formed by the mirror portions are designed to pick off the second harmonics or other even harmonics from the periphery of the fundamental. Further, the mirror portions need not be arranged in parallel as shown, but fixed at different angles or offsets, such that the reflected harmonics could be redirected in different directions.

One additional benefit for the primary application of lithography is that the inner opening 522 can be used to apodize or smooth the fundamental beam 501 to make the profile more flat-top by trimming light from the edges of the gaussian-shaped beam 15. This fundamental light could be redirected for use in metrology or inspection tool along with the other even harmonics collected.

### E. Cascaded Pick-Offs

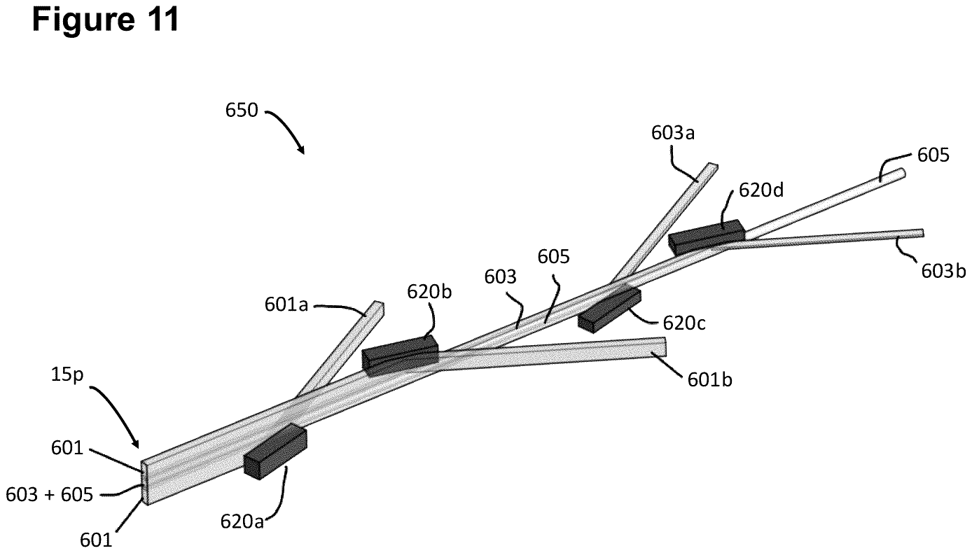

The various out-coupling techniques may be combined in optical systems designed to utilize multiple distinct harmonics for different metrology and/or inspection tools. FIG. 11 illustrates one example of a cascaded system 650 having a series of mirrors utilizing Method Three as described above. In this example, a portion 15p or slice of the source beam having on-axis odd harmonics (e.g., first harmonic 601, third harmonic 603, and fifth harmonic 605) is received into the cascaded system 650 and the various harmonics are picked-off, redirected, and/or passed using four different optical out-coupling stages.

The first out-coupling stage is a mirror 620a positioned to act as an outer optical aperture with a first angular orientation in order to reflect and redirect a first portion 601a of the fundamental (the bottom portion in this view) in a first direction. The remaining odd harmonics (including the remaining portion of the fundamental) pass by mirror 620a without any interaction.

The second out-coupling stage is an outer aperture mirror 620b, similar to mirror 620a, but having a second angular orientation different than the first angular orientation of mirror 620a, in order to reflect and redirect a second portion 601b of the fundamental (the top portion in this view) in a different, second direction. The remaining odd harmonics (third harmonic 603, fifth harmonic 605, and the residual portion of the fundamental 601) pass by mirror 620b without any interaction.

The third and fourth out-coupling stages are analogous to the first and second stages. The third stage is an outer aperture mirror 620c having a third angular orientation in order to reflect and redirect a first portion 603a of the third harmonic in a third direction. The fourth stage is an outer aperture mirror 620d having a fourth angular orientation in order to reflect and redirect a second portion 603b of the third harmonic in a fourth direction. The fifth harmonic 605 passes virtually untouched straight through all four stages of the cascaded system 650.

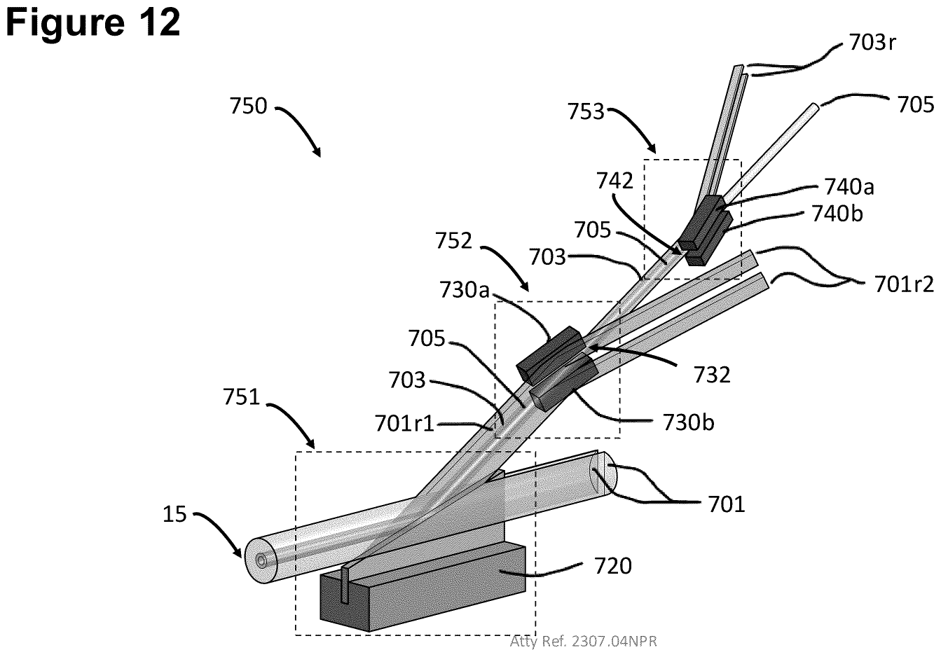

FIG. 12 is another example of a cascaded system 750 having a first stage 751 utilizing the thin inner aperture pick-off described as Method One above combined with two additional stages 752, 753 utilizing the outer aperture pick-off described as Method Three above. The first stage 751 is a thin wedge-shaped mirror 720 positioned to intersect with the beam 15 to reflect a small slice from the center of the beam, namely, the higher order odd harmonics 703, 705 and some residual portion 701r1 of the fundamental harmonic, toward a second stage 752, while most of the fundamental 701 passes the mirror.

The second stage 752 consists of two mirror portions 730a, 730b, acting as an outer optical aperture and having a gap 732 between them. The gap is sized to pass the higher order odd harmonics 703, 705 while the outer aperture formed by the mirror portions reflects most of the residual fundamental 701r2 toward, e.g., an inspection tool.

The third stage 753 also consists of two mirror portions 740a, 740b again acting as an outer aperture, but with an even smaller gap 742 sized to pass the fifth harmonic 705 while the outer aperture reflects the third harmonic 703r. In this example, the outer aperture mirror portions are parallel, but as in FIG. 11, the mirror portions could be fixed at different angles or positions along the incident beam path to redirect the incident beam in each stage in two different directions, e.g., to two different tools. Further, the mirror forming an outer optical aperture may be a single substrate having an appropriately sized notch or hole formed through the substrate acting as the gap to pass on-axis odd harmonics.

### F. Harmonic Separation Via Diffraction Grating

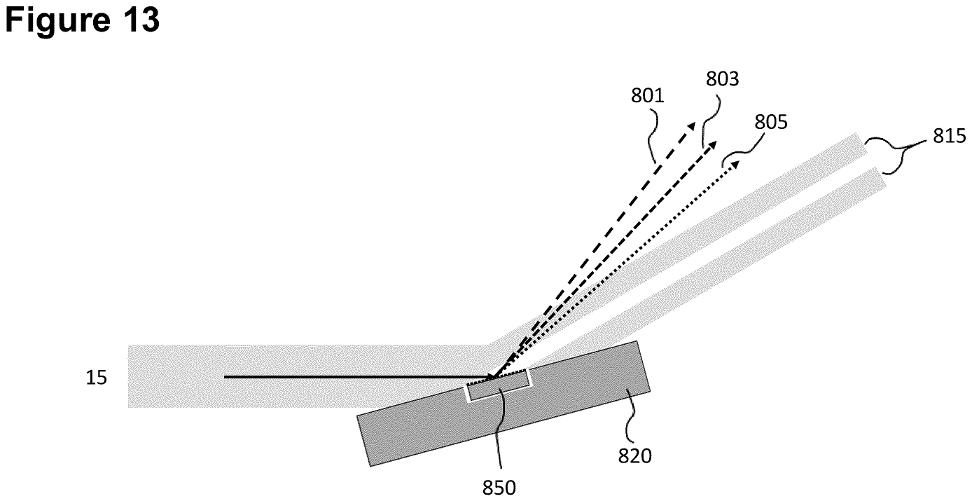

The out-coupling optics could include an optical diffraction grating 850, illustrated in FIG. 13, that may cover all of the mirror substrate 820, or just a portion of the mirror as shown. The grating 850 is designed as a reflective optic to redirect and separate the harmonic content of the source beam 15 (or a portion thereof) for use as a target beam in a metrology or inspection tool. Since the source beam 15 diffracts at a fixed cone angle as it exits the source, the grating 850 should be positioned with appropriate proximity to the source for the optic to capture the desired portion of the source beam. To out-couple the higher order harmonics, the grating should be positioned at a grazing angle since the diffraction efficiency falls off sharply with larger angles thereby limiting the power of harmonics reflected.

Assuming the diffraction grating 850 is positioned at an angle to the axis of the source beam 15, the odd harmonics of the source beam can be extracted and scattered by the grating, separate and apart from most of the source beam, which is simply reflected as beam 815 by the rest of the surface of mirror 820. As noted above, each harmonic will exhibit its own characteristic cone-shape divergence upon reflection from the grating 850. For example, if the source generates a 13.5 nm beam, then the grating structure may be designed to selectively reflect the first harmonic 801 (e.g., 13.5 nm), or the third harmonic 803 (e.g., 4.5 nm), or the fifth harmonic 805 (e.g., 2.7 nm), or all three, for redirection to one or more particular metrology or inspection tools.

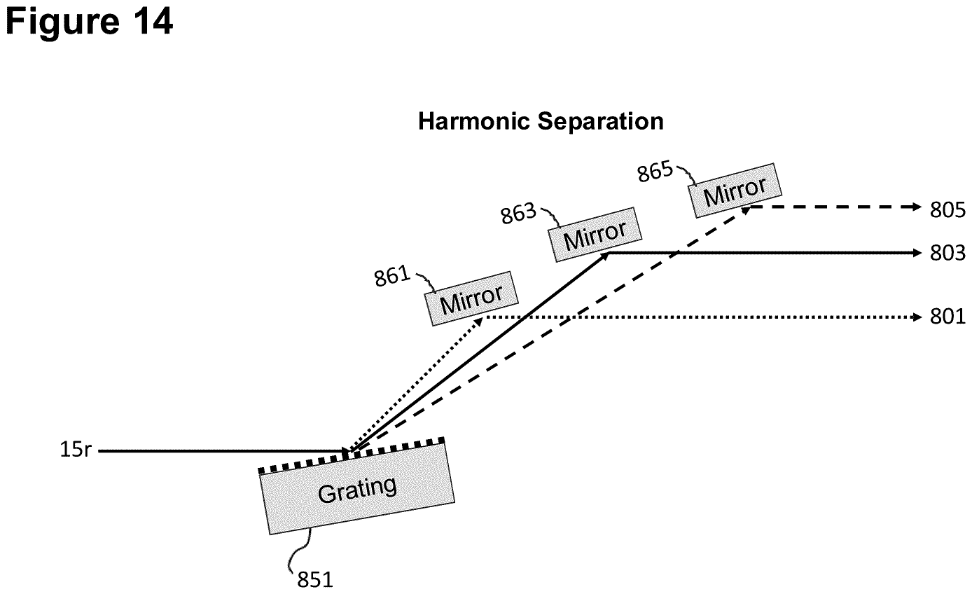

FIG. 14 illustrates another use of a grating 851 in an out-coupling system. The beam portion 15r includes the three odd harmonics 801, 803, 805, which are each diffracted in a different direction by the grating and redirected onto corresponding mirrors 861, 863, and 865, respectively, that in turn reflect each of the discrete harmonics along a different path to a different tool (not shown).

Construction of appropriate gratings to separate and redirect the desired wavelengths requires, for example, specifying the substrate, the coating for the surface of the substrate, such as a multilayer coating if necessary; the blazing and its pitch; or other grooves or slits etched into the grating surface.

### 3. Conclusion

High precision optical elements can be designed to select and “pick off” odd and/or even harmonics from an accelerator-based source beam for use in a metrology or inspection tool on the basis of the physics of the emission patterns from the accelerator-based light source. Thus, odd harmonics can be reflected by a mirror having an appropriately designed inner aperture, or passed through a small on-axis opening in a mirror having an outer aperture designed to reflect other harmonics. Even harmonics, as well as some of the fundamental harmonic, can be reflected by a mirror having an outer aperture and a large on-axis opening for passing the fundamental harmonic.

1. A system for coupling a light beam that is output from an accelerator-based light source for use in a semiconductor metrology or inspection system, wherein the light beam is comprised of a plurality of harmonics, each harmonic has a known emission pattern corresponding to the harmonic when output from the light source, comprising:
an optic positioned proximate to the light source and oriented at a specified angle to a beamline of the light source, the optic is configured to either redirect at least one of a plurality of harmonics and to pass a fundamental harmonic of the plurality of harmonics, or to pass at least one of the plurality of harmonics and to redirect the fundamental harmonic.

2. The system of claim 1, the optic further comprising:
an inner optical aperture positioned on-axis or near-axis with the beamline and sized to reflect at least one harmonic of the plurality of harmonics.

3. The system of claim 2, the inner optical aperture comprising:
a mirror oriented at a specified angle to the beamline axis, and configured and positioned to reflect the at least one harmonic and to pass the fundamental harmonic.

4. The system of claim 3, the mirror further comprising:
a thin profile and surface features designed to intersect with the beamline and reflect the at least one harmonic.

5. The system of claim 1, the optic further comprising:
an outer optical aperture positioned near-axis from the beamline and sized to reflect the fundamental harmonic, the optic having an on-axis or near-axis opening sized to pass a plurality of the harmonics.

6. The system of claim 5, the outer optical aperture comprising:
a mirror oriented at an appropriate angle to the beamline, the mirror has at least two mirror portions and the opening is a gap between the mirror portions, the gap sized to pass a plurality of the harmonics while the mirror portions reflect a substantial portion of the fundamental harmonic.

7. The system of claim 5, the outer optical aperture comprising:
a mirror oriented at an appropriate angle to the beamline, the opening is a notch or a hole formed through the mirror.

8. The system of claim 1, the optic further comprising:
an outer optical aperture positioned off-axis from the beamline and sized to reflect at least one even harmonic of the plurality of harmonics, the optic having an on-axis or near-axis opening sized to pass the fundamental harmonic.

9. The system of claim 8, the outer optical aperture comprising:
a mirror oriented at an appropriate angle to the beamline, the mirror having at least two mirror portions and the opening is a gap between the mirror portions, the gap sized to pass odd harmonics including the fundamental harmonic while the mirror portions reflect the at least one even harmonic.

10. The system of claim 1, the optic further comprising:
a mirror having a diffraction grating covering at least a portion of the mirror, the mirror oriented at a specified angle to the beamline, the diffraction grating having surface features designed to reflect at least one harmonic of the plurality of harmonics.

11. The system of claim 10, further comprising:
a plurality of mirrors, each one of the plurality of mirrors positioned to receive and redirect in a different direction from the other ones of the plurality of mirrors a corresponding harmonic of the plurality of harmonics from the diffraction grating.

12. A system for coupling a light beam that is output from an accelerator-based light source for use in a semiconductor metrology or inspection system, wherein the light beam is comprised of a plurality of harmonics, each harmonic has a known emission pattern corresponding to the harmonic when output from the light source, comprising:
a plurality of optics positioned proximate to the light source, each of the plurality of optics configured to pick off and redirect one portion of the plurality of harmonics and to pass another portion of the plurality of harmonics.

13. The system of claim 12, the plurality of optics further comprising:
a first optic configured to pick off and redirect a first portion of the plurality of harmonics and to pass a second portion of the plurality of harmonics; and
a second optic configured to pick off and redirect at least one harmonic from the second portion and to pass a remaining portion of the second portion of harmonics.

14. The system of claim 13, the first and second optics further comprising:
a plurality of mirrors oriented at different angles to a beamline of the light beam.

15. The system of claim 13, the first and second optics further comprising:
the plurality of mirrors is spaced apart from each other along the beamline.

16. The system of claim 12, the plurality of optics comprising:
a plurality of mirrors arranged proximate each other in sequence, a first one of the plurality of mirrors positioned to reflect a first portion of the light beam, and subsequent ones of the plurality of mirrors positioned to redirect a reflected portion from a prior mirror in the sequence of the plurality of mirrors.

17. A method for conditioning a light beam output from an accelerator-based light source for use in a semiconductor metrology or inspection system, wherein the light beam is comprised of a plurality of harmonics, each harmonic has a known emission pattern corresponding to the harmonic when output from the light source, comprising:
positioning an optic proximate to the output of the light source; and
orienting the optic at a specified angle to a beamline of the light source, the optic designed for reflecting and redirecting at least one harmonic of the plurality of harmonics to a metrology or inspection tool.

18. The method of claim 17, wherein the optic is designed for redirecting a first one of a plurality of harmonics of the light source to a metrology or inspection tool and for passing a substantial portion of the fundamental harmonic.

19. The method of claim 17, wherein the optic is designed for redirecting a first one of the plurality of harmonics of the light source to a metrology or inspection tool and for redirecting the fundamental harmonic.

20. The method of claim 17, wherein the optic is designed for redirecting each one of a plurality of the harmonics of the light source to a respective one of a plurality of metrology or inspection tools.
